(19) United States
(12) Patent Application Publication
(10) Pub. No.: US 2021/0037657 A1
(43) Pub. Date: Feb. 4, 2021

(54) MANUFACTURING METHOD OF CIRCUIT SUBSTRATE

(71) Applicant: Polytronics Technology Corp., Hsinchu (TW)

(72) Inventors: Hsun-Ching CHIANG, Hsinchu City (TW); Hsiang-Yun YANG, Jhudong Township (TW)

(21) Appl. No.: 16/844,468

(22) Filed: Apr. 9, 2020

(30) Foreign Application Priority Data
Jul. 30, 2019 (TW) 108126908

(51) Int. Cl. H05K 3/06

(52) U.S. Cl. CPC H05K 3/064; H05K 2203/0557

(57) ABSTRACT

A manufacturing method of a circuit substrate comprises the steps of providing a laminated substrate comprising an insulating layer and a circuit layer disposed on the insulating layer; forming a photoresist layer on the circuit layer; mechanically cutting the photoresist layer and a part of the circuit layer to form gaps; etching the circuit layer in the gaps until a surface of the insulating layer is exposed to form a circuit layout; and removing the photoresist layer to form the circuit substrate.

### BACKGROUND OF THE INVENTION

### (1) Field of the Invention

The present application relates to a manufacturing method of a circuit substrate, and more specifically, to a manufacturing method of a circuit substrate containing a thick circuit layer.

### (2) Description of the Related Art

With technology development, more devices are placed on the circuit substrate. Large current applications such as charging posts of electric vehicles or DC-DC converter demand high current conducting and holding capability for the circuit substrate. Because large current usually generates heat, the circuit substrate needs good heat dissipation. Therefore, a heat conductive circuit substrate with a thick copper layer is demanded in the market to withstand a current of 40 to 200 A.

Traditionally, a high-current and thermally conductive circuit substrate may contain a thick copper layer in which the copper layer is etched to form circuit layout. However, the copper layer is usually thicker than 0 7 mm, or up to 2-5 mm and therefore it takes more than 24 hours to form the circuit layout by etching. Circuit line gaps of the etched circuit are limited to circuit thickness and the line gap is usually 1-1.3 times the circuit thickness. Etching of thick copper layer wastes a lot of copper and the use of strong acidic solution for etching is detrimental to environment.

In view of the above, the making of the traditional high-current and thermally conductive circuit substrate has shortcomings and deficiency and needs to be improved.

### SUMMARY OF THE INVENTION

The present application provides a manufacturing method of a circuit substrate in which two different processes are used to make the circuit layout of the circuit substrate. This method breaks through the difficulty on making circuits in a thick circuit layer and shortens production time. It is suitable for high-current applications such as electric vehicle charging.

A manufacturing method of a circuit substrate comprises the steps of providing a laminated substrate comprising an insulating layer and a circuit layer disposed on the insulating layer; forming a photoresist layer on the circuit layer; mechanically cutting the photoresist layer and a part of the circuit layer to form gaps; etching the circuit layer in the gaps until a surface of the insulating layer is exposed to form a circuit layout; and removing the photoresist layer to form the circuit substrate.

In an embodiment, a depth of a circuit layer removed by mechanically cutting in the gap is 50-90% of a thickness of the circuit layer.

In an embodiment, the thickness of the circuit layer is 0.4-6 mm.

In an embodiment, the circuit layer is a copper layer.

In an embodiment, the laminated substrate further comprises a metal substrate disposed on a bottom surface of the insulating layer, and the metal substrate may be a copper layer or an aluminum layer.

In an embodiment, the gap has a sidewall with an angle of 75-90 degrees.

In an embodiment, the gap has a top width W1 and a bottom width W2. A ratio W2/W1 is in the range of 0.5-0.9.

In an embodiment, the gap has a top width W1 and the circuit layer has a thickness H. A ratio H/W1 is in the range of 1-5.

In an embodiment, the step of etching performs less than 30% over etch.

In an embodiment, the insulating layer has a thermal conductivity of 2-20W/m·K.

The manufacturing method of a circuit substrate of the present application can speed up making the layout of the circuit layer. Moreover, the gap can be made deeper based on a same gap width. This method breaks through the limitation that the width is usually equal to or larger than the depth for a traditional gap.

### BRIEF DESCRIPTION OF THE DRAWINGS

The present application will be described according to the appended drawings in which:

FIG. 1 through FIG. 5 show the method of manufacturing a circuit substrate in accordance with an embodiment of the present application;

FIG. 6 shows an enlarged view of a gap in FIG. 5; and

FIG. 7 shows a flow chart for manufacturing a circuit substrate in accordance with an embodiment of the present application.

### DETAILED DESCRIPTION OF THE INVENTION

The making and using of the presently preferred illustrative embodiments are discussed in detail below. It should be appreciated, however, that the present application provides many applicable inventive concepts that can be embodied in a wide variety of specific contexts. The specific illustrative embodiments discussed are merely illustrative of specific ways to make and use the invention, and do not limit the scope of the invention.

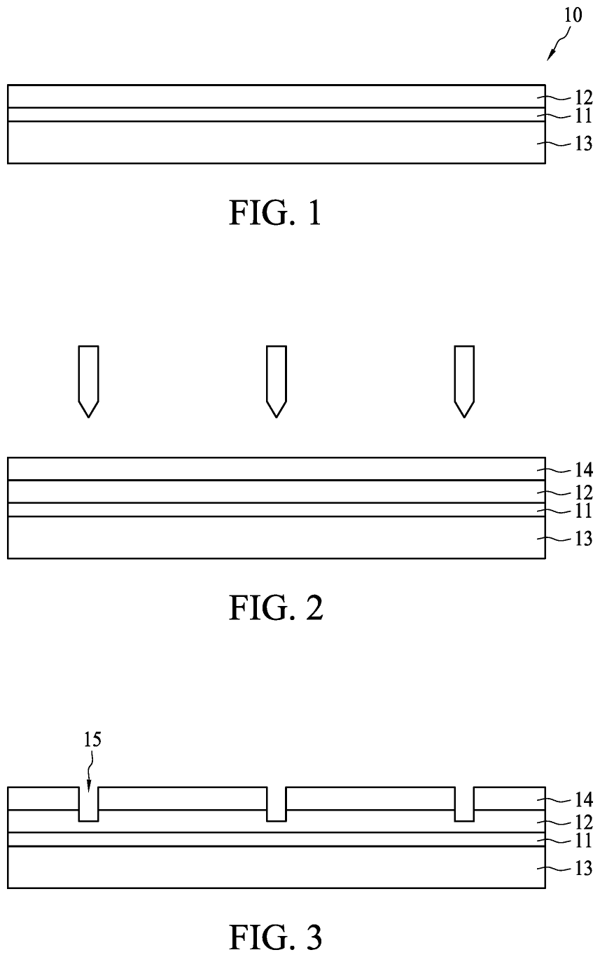

FIG. 1 through FIG. 5 show a process of making a circuit substrate in accordance with an embodiment of the present application. In FIG. 1, a laminated substrate 10 comprises a metal substrate 13, an insulating layer 11 and a circuit layer 12. The insulating layer 11 is disposed on an upper surface of the metal substrate 13 and the circuit layer 12 is disposed on the upper surface of the insulating layer 11 to form a laminated structure. The metal substrate 13 may have a thickness of 0.3-5 mm and may be a copper layer or an aluminum layer for heat dissipation. The insulating layer 11 may have a thickness of 0.05-0.25 mm and may be a polymer layer containing thermally conductive filler. The thermal conductivity of the insulating layer 11 may be 2-20W/m·K, e.g., 5W/m·K, 8W/m·K or 12W/m·K. The circuit layer 12 may have a thickness of 0.4-6 mm, e.g., 1 mm, 3 mm or 5 mm, and may be a copper layer or an aluminum layer.

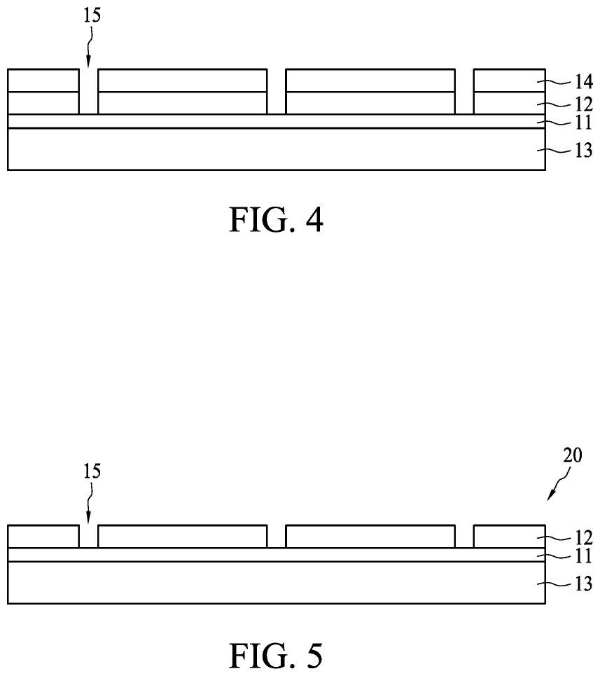

In FIG. 2 and FIG. 3, a photoresist layer 14 is formed on the circuit layer 12. In an embodiment, the photoresist layer 14 has a thickness of 20-30 μm. The photoresist layer 14 and a part of the circuit layer 12 are mechanically cut out by a cutter to form gaps 15 at positions with reference to a circuit layout. As a result, the circuit layer 12 still has a portion remaining in the gaps 15. In FIG. 4, the circuit layer 12 in the gaps 15 is etched until a surface of the insulating layer 11 is exposed. In an embodiment, chemical etching is employed and etchant may use acidic solution, e.g., copper chloride. A ratio of the thickness of the circuit layer 12 to be etched to the photoresist thickness is 16-200. Afterwards, the photoresist layer 14 is removed to form a circuit substrate 20 as shown in FIG. 5.

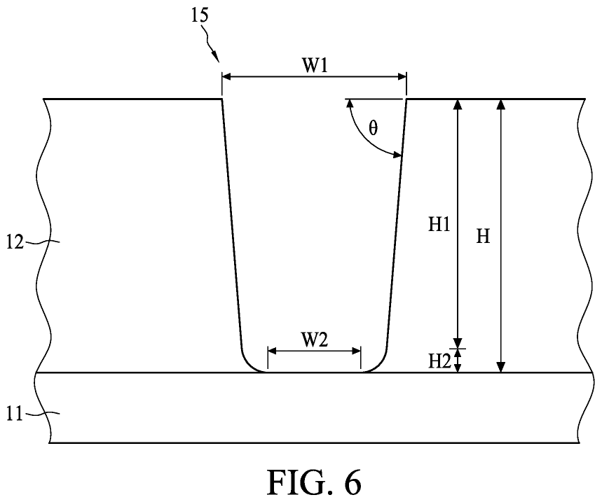

FIG. 6 shows details of a gap 15. For clarity and simplicity, the metal substrate is omitted in FIG. 6. In the formation of the gap 15 in the circuit layer 12, the circuit layer 12 is mechanically cut to a depth H1 and then is etched to a surface of the insulating layer 11 with a depth H2. The depth of the gap 15 is equal to the thickness H of the circuit layer 12, i.e., H=H1+H2. The depth H1 removed by mechanically cut is 50-90% of the thickness H, i.e., H1/H=50-90%. For example, H1/H=60% or 80%. If H1/H is less than 50%, making the gap 15 becomes slow and the opening or the top of the gap 15 is enlarged. If H1/H is greater than 90%, there is a concern to cut the insulating layer 11 due to inaccurate control of mechanical cutting. An angle θ between a sidewall of a portion of the gap 15 formed by mechanical cutting and a horizontal plane is 75-90°. If over-etched, the opening of the gap 15 is enlarged and the angle θ of the sidewall of the gap 15 becomes smaller, e.g., less than 70°. As a consequence, circuit quality would be deteriorated. In accordance with the present application, the etching step performs less than 30% or 20% over etch, and therefore the bottom sidewalls of the gap 15 may be in the form of arcs. If the top width of the gap 15 is W1 and the bottom width of the gap 15 is W2, W2/W1 is 0.5-0.9, e.g., 0.6 or 0.8. Because wet etching is isotropic, the gap cannot be wet etched deeply and the width of the gap is usually equal to or larger than the depth of the gap. In accordance with the present application, the gap 15 can be made deeper with H/W1 of 1-5. Table 1 shows the dimensions of gaps in accordance with embodiments E1-E7 of the present application, the unit of H, H1, H2, W1 and W2 is millimeters.

TABLE 1

| | H | H1 | H2 | W1 | W2 | θ | W2/W1 | H/W1 |
|---|---|---|---|---|---|---|---|---|
| E1 | 0.4 | 0.3 | 0.1 | 0.3 | 0.25 | 85° | 0.83 | 1.33 |
| E2 | 1 | 0.8 | 0.2 | 0.5 | 0.35 | 85° | 0.7 | 2 |
| E3 | 3.2 | 2.9 | 0.3 | 1.8 | 1.2 | 84° | 0.67 | 1.78 |
| E4 | 2 | 1.8 | 0.2 | 0.5 | 0.3 | 87° | 0.6 | 4 |
| E5 | 5 | 4.1 | 0.9 | 5 | 4.2 | 84° | 0.84 | 1 |
| E6 | 2.5 | 2 | 0.5 | 2 | 1 | 75° | 0.5 | 1.25 |
| E7 | 3 | 1.8 | 1.2 | 0.8 | 0.5 | 85° | 0.63 | 3.75 |

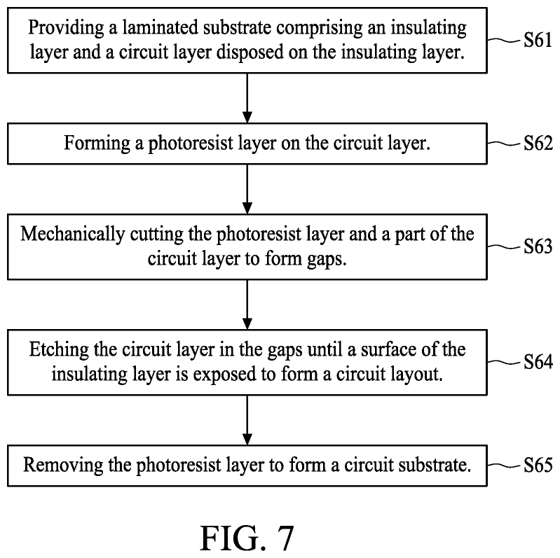

is A flow chart of the manufacturing method of a circuit substrate in accordance with the present application is shown in FIG. 7. Step S61: Providing a laminated substrate comprising an insulating layer and a circuit layer disposed on the insulating layer. Step S62: Forming a photoresist layer on the circuit layer. Step S63: Mechanically cutting the photoresist layer and a part of the circuit layer to form gaps. Step S64: Etching the circuit layer in the gaps until a surface of the insulating layer is exposed to form a circuit layout. Step S65: Removing the photoresist layer to form a circuit substrate.

Traditionally, the circuit layout with gaps formed by a single process of wet etching has a limitation that the width of the gap is not less than the depth of the gap and the depth of the gap is equal to the thickness of the circuit layer. To form a deep gap or a narrow gap, it is difficult to fully etch the circuit layer down to the bottom and the circuit layer still remains in the gap. Moreover, the deep or narrow gap may cause longer etching time and therefore the gap in the circuit layer of a thickness more than 0 4 mm would not be manufactured by etching. The thick circuit layer is a bottleneck hard to breakthrough by traditionally wet etching. In combination of mechanical cutting and chemical or wet etching in accordance with the present application, a circuit layer of a thickness of 0.4-6 mm can be made to form gaps of circuit layout. For example, for a circuit layer of a thickness up to 5 mm made by the method of the present application, the line gap can be 0.7-1 mm and etching factor is greater than 9 This resolves the problem that line gap is limited to the circuit layer thickness. The method of the present application overcomes etching inefficient problems and is suitable for high current applications of the circuit substrate with a thick circuit layer.

The above-described embodiments of the present invention are intended to be illustrative only. Numerous alternative embodiments may be devised by persons skilled in the art without departing from the scope of the following claims.

What is claimed is:

1. A manufacturing method of a circuit substrate, comprising:
providing a laminated substrate comprising an insulating layer and a circuit layer disposed on the insulating layer;
forming a photoresist layer on the circuit layer;
mechanically cutting the photoresist layer and a part of the circuit layer to form gaps;
etching the circuit layer in the gaps until a surface of the insulating layer is exposed to form a circuit layout; and
removing the photoresist layer to form the circuit substrate.

2. The manufacturing method of claim 1, wherein a depth of a circuit layer removed by mechanically cutting in the gap is 50-90% of a thickness of the circuit layer.

3. The manufacturing method of claim 1, wherein the thickness of the circuit layer is 0.4-6 mm

4. The manufacturing method of claim 1, wherein the circuit layer is a copper layer.

5. The manufacturing method of claim 1, wherein the laminated substrate further comprises a metal substrate disposed on a bottom surface of the insulating layer, and the metal substrate is a copper layer or an aluminum layer.

6. The manufacturing method of claim 1, wherein the gap has a sidewall with an angle of 75-90 degrees.

7. The manufacturing method of claim 1, wherein the gap has a top width W1 and a bottom width W2 and a ratio W2/W1 is in the range of 0.5-0.9.

8. The manufacturing method of claim 1, wherein the gap has a top width W1 and the circuit layer has a thickness H and a ratio H/W1 is in the range of 1-5.

9. The manufacturing method of claim 1, wherein the step of etching performs less than 30% over etch.

10. The manufacturing method of claim 1, wherein the insulating layer has a thermal conductivity of 2-20W/m·K.
